(19) United States
(12) Patent Application Publication
(10) Pub. No.: US 2011/0027997 A1
(43) Pub. Date: Feb. 3, 2011

(54) POLISHING LIQUID FOR CMP AND POLISHING METHOD

(75) Inventors: Takashi Shinoda, Ibaraki (JP); Takaaki Tanaka, Ibaraki (JP); Mamiko Kanamaru, Ibaraki (JP); Jin Amanokura, Ibaraki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: HITACHI CHEMICAL COMPANY, LTD., Tokyo (JP)

(21) Appl. No.: 12/937,463

(22) PCT Filed: Apr. 16, 2009
(86) PCT No.: PCT/JP2009/057641

§ 371 Date: Oct. 12, 2010

(30) Foreign Application Priority Data
Apr. 16, 2008 (JP) 2008-106740
Jan. 6, 2009 (JP) 2009-000875

(51) Int. Cl. H01L 21/302; C09K 3/14

(52) U.S. Cl. 438/693; 252/79.1; 257/E21.304

(57) ABSTRACT

The present invention can provide a polishing liquid for CMP having good dispersion stability and a high polishing rate in polishing of interlayer insulating films and a polishing method. Disclosed a polishing liquid for CMP comprising: a medium; and colloidal silica particles dispersed in the medium, a blending amount of the colloidal silica particles being 2.0 to 8.0% by mass relative to 100% by mass of the polishing liquid,
wherein the colloidal silica particles satisfy the following conditions (1) to (3):
(1) a two-axis average primary particle diameter (R₁) obtained from images of twenty arbitrarily selected colloidal silica particles observed by a scanning electron microscope is within the range of 35 to 55 nm;
(2) a value S₁/S₀ obtained by dividing a specific surface area (S₁) of a colloidal silica particle measured by BET method by a calculated specific surface area (S₀) of a true sphere having the same particle diameter as the two-axis average primary particle diameter (R₁) determined by (1) above is 1.20 or less; and
(3) a ratio, association degree: R_{S}/R₁, of a secondary particle diameter (R_{S}) of the colloidal silica particles measured with a dynamic light scattering particle size distribution analyzer and the two-axis average primary particle diameter (R₁) determined by (1) above in the polishing liquid for CMP is 1.30 or less.

### TECHNICAL FIELD

The present invention relates to a polishing liquid for CMP used in polishing for a wiring forming process of a semiconductor device and a polishing method.

### BACKGROUND ART

In recent years, high integration and high performance of semiconductor integrated circuits (also referred to as LSI hereinafter) have been realized and novel fine processing techniques have been developed. Chemical and Mechanical Polishing (also referred to as CMP hereinafter) is one of these techniques and has been frequently used in an LSI manufacturing process, for planarizing interlayer insulating films, for forming metal plugs, and for forming embedded wirings in a process of forming multi-level wirings. This technique is disclosed in Patent Literature 1, for example.

Further, use of copper and copper alloys as conductive materials to be wiring materials has been attempted in recent years in order to attain realization of high performance of LSI.

However, there is a difficulty in subjecting copper or copper alloys to the fine processing based on a dry etching method which has been frequently employed for forming conventional aluminum alloy wirings.

Accordingly, a so-called damascene process has been mainly utilized, in which thin films of copper or copper alloys are deposited on an insulating film having grooves which are provided in advance so as to fill the grooves and thereby an embedded wiring is formed by removing the thin film at an area other than the grooves by CMP. This technique is disclosed in Patent Literature 2, for example.

A general metal CMP method of polishing conductive materials such as copper or copper alloys comprises the steps of:

applying a polishing pad (also referred to as polishing cloth) to a circular polishing table (platen);
pressing the surface of a substrate, on which a metal film is formed, onto the surface of the polishing pad while the surface of the polishing pad is immersed with a metal polishing liquid;
rotating the polishing table while a predetermined pressure (referred to as a polishing pressure hereinafter) is applied to the back surface of the polishing pad; and
removing a metal film at convex regions by relative mechanical friction between the polishing liquid and the metal film at the convex regions.

The metal polishing liquid used for CMP usually contains an oxidant and polishing particles, and may further contains a metal oxide dissolving agent and a protective film forming agent, if necessary. It is considered that the basic mechanism of the polishing includes a step of oxidizing the surface of the metal film with the oxidant, and a step of scraping the oxide layer with the polishing particles.

Since the oxide layer on the surface of the metal in the concave regions is nearly not brought into contact with the polishing pad and is not affected by the scraping carried out by the polishing particles, the metal layer at the convex regions is removed with progression of the CMP and the surface of the substrate is planarized. Details of this process are described in Non-Patent Literature 1, for example.

As a method of enhancing the polishing rate by CMP, it is believed that adding a metal oxide dissolving agent is effective. It is interpreted such that the scraping effect of the polishing particles is enhanced by dissolving particles of the metal oxide scraped by the polishing particles in the polishing liquid (Hereinbelow, this process is referred to as “etching”).

The polishing rate by CMP increases by way of adding the metal oxide dissolving agent. However, owing to the addition of the metal oxide dissolving agent, the surface of the metal film is further oxidized by the oxidant when the surface of the metal film in the concave regions is etched and thereby exposed. Therefore, if this is repeated, further etching of the metal film in the concave regions occurs. For this reason, the central region of the embedded metal wiring is depressed, forming a disk-like shape after the polishing (a phenomenon called dishing hereinafter), and therefore the planarization effect is impaired.

In order to prevent the dishing, a protective film forming agent is further added. The protective film forming agent is an agent for forming a protective film on the oxide layer on the surface of the metal film and thereby preventing the oxide layer from being dissolved into the polishing liquid. It is desired that this protective film is readily scraped by the polishing particles so that the polishing rate by CMP is not lowered.

In order to suppress the dishing or corrosion of copper or copper alloys during the polishing and to form highly reliable LSI wirings, there has been provided a method of using a polishing liquid for CMP containing an amino acetic acid such as glycine or a sulfuric amide acid as a metal oxide dissolving agent and BTA (benzotriazole) as a protective film forming agent. This technique is described in Patent Literature 3, for example.

Meanwhile, as illustrated in FIG. 1(a), as an underlayer of a conductive material 3 formed from a metal layer for wiring such as copper or copper alloys, a layer of barrier metal 2 (referred to as a barrier layer hereinafter) is formed for preventing copper from diffusing into the interlayer insulating film 1 or for improving adhesion. As for the barrier metal 2, a tantalum compound such as tantalum, tantalum alloys or tantalum nitrides is used, for example. Accordingly, the exposed barrier metal 2 should be removed by a CMP process at the regions other than the wiring regions at which the conductive material is embedded.

However, since the barrier metal 2 is more rigid than the conductive material 3, sufficient polishing rate cannot be obtained even by a combination of polishing components for the conductive material. Moreover, flatness is often impaired. Therefore, a two-step polishing method including a first step of polishing the conductive material 3 from the state of FIG. 1(a) to the state of FIG. 1(b) and a second step of polishing the barrier metal 2 from the state of FIG. 1(b) to the state of FIG. 1(c) has been examined.

In general, in the second polishing process where the barrier metal 2 is polished, a portion of the thickness of the interlayer insulating film 1 at convex regions is also polished in order to improve flatness (i.e., over-polishing). While a silicon oxide film has been mainly used as the interlayer insulating film 1, silicon materials or organic polymers having a lower dielectric constant than the silicon oxide film have been attempted to be used in recent years in order to attain realization of high performance of LSI. Examples thereof include organosilicate glass, of which a starting material is trimethyl silane and which is a low dielectric constant (Low-k) film, and a wholly aromatic cyclic system Low-k film.

### Prior Art Literatures

### Patent Literature

Patent Literature 1: U.S. Pat. No. 4,944,836

Patent Literature 2: Japanese Patent No. 1969537

Patent Literature 3: Japanese Patent No. 3397501

### Non-Patent Literature

Non-Patent Literature 1: Journal of Electrochemical Society, 1991, Vol. 138, No. 11, p. 3460-3464

### DISCLOSURE OF THE INVENTION

### Technical Problem

In order to shorten a time required for a polishing process and to improve throughput of the process, polishing rate for a barrier metal 2 and an interlayer insulating film 1 is preferably high. In order to improve the polishing rate for the interlayer insulating film 1, it can be considered for example, to increase the content of polishing particles that are contained in a polishing liquid for CMP or to increase the particle diameter of polishing particles.

However, dispersion stability tends to get deteriorated in any of the above cases, and polishing particles become easily precipitated. That is, when a polishing liquid is used after being stored for a certain period of time, the polishing rate of the interlayer insulating film may easily get decreased, which causes a problem such that flatness cannot be obtained. Thus, there is a demand for a polishing liquid that has the same polishing rate for the barrier layer as the conventional polishing liquid for the barrier layer and also has a sufficiently high polishing rate for the interlayer insulating film.

In view of the problems described above, an object of the present invention is to provide a polishing liquid for CMP having good dispersion stability of polishing particles in the polishing liquid for CMP, can polish an interlayer insulating film at a high polishing rate, and can polish a barrier layer at a high polishing rate while maintaining such characteristic.

Another object of the invention is to provide a polishing method suitable for manufacturing a highly reliable and low-cost semiconductor device which is excellent in miniaturization, thinning of film thickness, dimensional accuracy and electrical characteristics.

As a result of carrying out various studies to solve the problems described above, according to the invention, colloidal silica particles are used as polishing particles, and the followings are found to be important factors, i.e., the average primary particle diameter of the colloidal silica particles is within a certain range, the particles have a shape which closely resembles a true sphere, and the particles are in a slightly associated state with each other in the polishing liquid for CMP.

### Solution to Problem

More specifically, the present invention relates to a polishing liquid for CMP comprising: a medium; and colloidal silica particles dispersed in the medium, and

it is found that the colloidal silica particles have favorable properties when satisfying all of the following conditions (1) to (3):

(1) a two-axis average primary particle diameter (R₁) obtained from the images of twenty arbitrarily selected colloidal silica particles observed by a scanning electron microscope (SEM) is within the range of 35 to 55 nm;

(2) a value S₁/S₀ obtained by dividing the specific surface area (S₁) of the colloidal silica particles measured by BET method by a calculated specific surface area (S₀) of a true sphere having the same particle diameter as the two-axis average primary particle diameter (R₁) determined by (1) above is 1.20 or less; and

(3) a ratio, association degree: R_{S}/R₁, of the secondary particle diameter (R_{S}) of the colloidal silica particles measured with a dynamic light scattering particle size distribution analyzer with respect to the two-axis average primary particle diameter (R₁) determined by (1) above in the polishing liquid for CMP is 1.30 or less,

and also have more favorable properties when the blending amount of colloidal silica particles is 2.0 to 8.0% by mass with respect to 100% by mass of the polishing liquid for CMP.

The disclosure of the invention is related to the subjects described in Japanese Patent Application No. 2008-106740 which has been filed on Apr. 16, 2008 and in Japanese Patent Application No. 2009-000875 which has been filed on Jan. 6, 2009, and the disclosure of which is incorporated herein by way of references.

### EFFECTS OF THE INVENTION

According to the invention, a polishing liquid for CMP which is useful for polishing an interlayer insulating film at a high polishing rate can be obtained. As a result, throughput can be improved by shortening the time required for polishing process.

Further, even in the case in which the addition amount of the polishing particles is relatively small compared to the conventional techniques, a high polishing rate for an interlayer insulating film can be obtained.

Further, since it is satisfactory that only a small addition amount of the polishing particles is used, the polishing liquid can be concentrated to a higher concentration compared to conventional liquid. Accordingly, it has better convenience in terms of storage and transport. In addition, an application method, which is customized to meet the needs of customers and has high level of freedom, can be provided.

Still further, the polishing method of the invention, which carries out chemical and mechanical polishing using this polishing liquid for CMP, has high productivity and is suitable for manufacturing a highly reliable semiconductor device and other electronic instruments which are excellent in miniaturization, thinning of film thickness, dimensional accuracy and electrical characteristics.

### BRIEF DESCRIPTION OF THE DRAWINGS

FIG. 1 is a cross sectional diagram showing the progress of a general damascene process. Specifically, FIG. 1(a) is a state before polishing, FIG. 1(b) is a state in which a metal for wiring (i.e., conductive material) is polished until a barrier layer is exposed, and FIG. 1(c) is a state in which polishing is carried out until a convex region of an interlayer insulating film is exposed.

FIG. 2 shows an example of a particle shape from which the two-axis average primary particle diameter is calculated.

FIGS. 3(a) to 3(d) are cross sectional diagrams showing an example of a process of forming a wiring layer in a semiconductor device.

FIG. 4 is a cross sectional diagram showing an example of over-polishing during a second polishing process.

### BEST MODE FOR CARRYING OUT THE INVENTION

The polishing liquid for CMP of the present invention is a polishing liquid for CMP comprising: a medium; and colloidal silica particles dispersed in the medium as polishing particles, in which the colloidal silica particles satisfies all the following conditions (1) to (3):

(1) a two-axis average primary particle diameter (R₁) obtained from the images of twenty arbitrarily selected colloidal silica particles observed by a scanning electron microscope (SEM) is within the range of 35 to 55 nm;

(2) a value S₁/S₀ obtained by dividing the specific surface area (S₁) of the colloidal silica particles measured by BET method by a calculated specific surface area (S₀) of a true sphere having the same particle diameter as the two-axis average primary particle diameter (R₁) determined by (1) above is 1.20 or less; and

(3) a ratio, association degree: R_{S}/R₁, of the secondary particle diameter (R_{S}) of the colloidal silica particles measured with a dynamic light scattering particle size distribution analyzer and the two-axis average primary particle diameter (R₁) determined (1) above in the polishing liquid for CMP is 1.30 or less. It is preferable that the blending amount of the above colloidal silica particles is 2.0 to 8.0% by mass relative to 100% by mass of the polishing liquid for CMP.

Hereinbelow, meanings of the above (1) to (3) and each component which can be comprised in the polishing liquid for CMP will be explained in detail.

### (I. Colloidal Silica Particles)

(I-i. Two-Axis Average Primary Particle Diameter)

As the colloidal silica added to the polishing liquid for CMP of the invention, those having good dispersion stability in a polishing liquid and causing relatively a few polishing scratches by CMP are preferable. Specifically, colloidal silica having a two-axis average primary particle diameter within the range of 35 nm to 55 nm is preferable, wherein the diameter is obtained from the result of observation of twenty random particles by a scanning electron microscope. Colloidal silica having the diameter within the range of 40 nm to 50 nm is more preferable. When the two-axis average primary particle diameter is equal to 35 nm or more, the polishing rate for the interlayer insulating film is improved. Further, when it is equal to 55 nm or less, the dispersion stability in polishing liquid tends to improve.

According to the invention, the two-axis average primary particle diameter is obtained as follows. First, an appropriate amount of colloidal silica, (solid content concentration within the range of to 40% by weight, in general), that is usually dispersed in water, is taken and put into a container. Next, a wafer having patterned wirings thereon is cut into cubes with a size of 2 square-cm to produce chips and the resulting chip is immersed in the container for approximately 30 seconds. After that, the chip is taken out of the container and transferred to a container, which contains pure water therein, and rinsed for approximately 30 seconds. The chip is then dried by nitrogen blowing. The chip is placed on a sample stage for SEM observation. With application of acceleration voltage of 10 kV, the particles are observed with a magnification ratio of 100,000 and an image is taken. Twenty particles are arbitrarily selected from the obtained image.

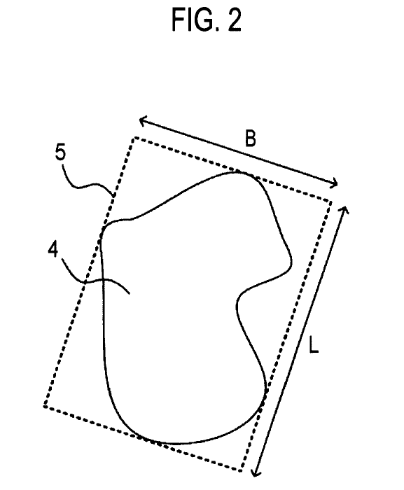

For example, when the selected particle has a shape shown in FIG. 2, a rectangular shape (i.e., circumscribed rectangle 5) is drawn to have the longest major axis while circumscription is made around particle 4. When the length of the major axis and the length of the minor axis of the circumscribed rectangle 5 is L and B, respectively, the two-axis average primary particle diameter is calculated as (L+B)/2 for a single particle. The same process is repeated for the twenty random particles, and the average value obtained therefrom is defined as the two-axis average primary particle diameter (R₁) of the invention.

(I-ii. Association Degree)

Regarding the colloidal silica used in the polishing liquid of the invention, in order to obtain preferable polishing rate for the interlayer insulating film and favorable dispersion stability in the polishing liquid, the association degree of the particles is preferably 1.30 or less, and more preferably 1.25 or less. According to the invention, the association degree is defined as the ratio of the secondary particle diameter (R_{S}) of the colloidal silica particles to the two-axis average primary particle diameter (R₁) explained in the section (I-i) above, that is, the value R_{S}/R₁.

Herein, regarding the above secondary particle diameter (R_{S}), an appropriate amount of the polishing liquid for CMP is taken and diluted with water, if necessary, to be within the range of scattering light intensity that is required by a dynamic light scattering particle size distribution analyzer, and therefore a sample for measurement is obtained. Then, this sample for measurement is introduced into a dynamic light scattering particle size distribution analyzer, and the obtained D50 value is taken as the average particle diameter. As for the dynamic light scattering particle size distribution analyzer having such function, N5 (model number) manufactured by Beckman Coulter, Inc. can be mentioned. In addition, when the polishing liquid for CMP is fractionated or concentrated for storage as described below, it is possible that a sample is prepared from a slurry containing colloidal silica according to the method described above and then the secondary particle diameter is measured.

As explained in the above, the condition that colloidal silica has a small association degree means that a unit particle closely resembles a sphere, and a greater number of unit particles contained in the polishing liquid will be in brought into contact with a certain subject to be polished (i.e., wafer surface). Specifically, given the cases in which the association degree is 1 and 2, respectively, but the particles are present in the same % by mass in the polishing liquid for CMP, the number concentration of the particles for the case in which the association degree is 1 is twice as many as the case in which the association degree is 2, and therefore more unit particles can be brought into contact with the wafer surface. As a result, it can be considered that the polishing rate for the interlayer insulating film is increased.

In addition, it can be also considered that, since a single particle closely resembling a sphere has a greater area that can be brought into contact with a polishing surface, the polishing rate for the interlayer insulating film is increased.

(I-iii. True Sphericity)

The colloidal silica used for the polishing liquid for CMP of the invention is preferably a particle closely resembling a sphere. From this view point, when determining the BET specific surface area obtained by measurement and the theoretical value of specific surface area for a case in which the particle has a true sphere shape, a small ratio between them (i.e., a measured value/a theoretical value, Hereinbelow, referred to as true sphericity) is required. Specifically, the true sphericity is preferably 1.20 or less, more preferably 1.15 or less, and still more preferably 1.13 or less.

A method of determining the true sphericity is explained below. First, according to the method described in the above section (I-i), the two-axis average primary particle diameter (R₁) is obtained from the result of observation of twenty arbitrarily selected polishing particles by a scanning electron microscope.

Next, the theoretical specific surface area (S₀) of an imaginary true spherical particle having the same particle diameter (R₁) as in the above and made of the same material as in the above is calculated according to the following equation (1).

S₀=4π(R₁/2)²/[(4/3)π(R₁/2)³×d] (1)

(in the equation (1), R₁ [m] represents the two-axis average primary particle diameter and d [g/m³] represents the density of the particle)

The density d can be measured according to a vapor phase replacement method, and the value 2.05×10⁶ [g/m³] may be used for the true density of colloidal silica particles.

Next, the specific surface area (S₁) for a real particle is measured. As a general method for the measurement, BET method can be mentioned. According to this method, an inert gas such as nitrogen is physically adsorbed onto the surface of a solid particle at a low temperature and a specific surface area is estimated from the cross sectional area of a molecule and an adsorption amount of the adsorbent.

Specifically, about 100 g of colloidal silica sample dispersed in water is put into a dryer and dried at 150° C. to obtain silica particles. The resulting silica particles (about 0.4 g) is put into to a measurement cell of an apparatus for measuring the BET specific surface area, and then deaerated at 150° C. under vacuum for 60 minutes. As for an apparatus for measuring the BET specific surface area, NOVA-1200 (manufactured by YUASA-IONICS Co., Ltd.), which is an apparatus for measuring a specific surface area and distribution of micropores based on gas adsorption, is used. The area is obtained according to a constant volume method wherein nitrogen gas is used as an adsorption gas, and the obtained value is taken as a BET specific surface area. The measurement is carried out twice and the average value is taken as the BET specific surface area of the invention.

According to the BET theory, a physically adsorbed amount (v) in a molecular layer at a certain adsorption equilibrium pressure P is expressed with the following equation (2).

v=vₘcP/(Pₛ−P)(1−(P/Pₛ)+c(P/Pₛ)) (2)

Herein, Pₛ represents a saturated vapor pressure of an adsorbate gas at a measurement temperature, vₘ represents an adsorption amount in a single molecular layer (mol/g) and c represents a constant. The equation (2) can be re-arranged as follows.

P/v(Pₛ−P)=1/vₘc+(c−1)/vₘc·P/Pₛ (3)

With respect to the above equation, when P/v(Pₛ−P) is plotted against the relative pressure P/Pₛ, a linear line is obtained. For example, when P/v(Pₛ−P) is measured at three points, 0.1, 0.2 and 0.3, as measuring points for measuring a relative pressure, and the vₘ value obtained from the slope and the intercept of the linear line is multiplied by the area taken by a nitrogen molecule (m²) and the Avogadro number (number/mol), the resulting value corresponds to the specific surface area. Total surface area of the particles that are contained in a powder per unit mass is the specific surface area.

By dividing the measured specific surface area (S₁) of a particle measured by BET method by the theoretical specific surface area (S₀) of an imaginary spherical particle as obtained above, the true sphericity (S₁/S₀) can be determined.

For producing colloidal silica, the two-axis average primary particle diameter, association degree and true sphericity of colloidal silica can be controlled to a certain degree according to the common knowledge of colloidal silica manufactures, and the colloidal silica can be easily obtained from a known colloidal silica manufacturer. Furthermore, if the above described characteristics are satisfied, two or more kinds of polishing particles can be used in combination for the polishing liquid for CMP of the invention.

As described above, when the true sphericity of colloidal silica is close to 1, it means that each particle closely resembles a sphere, and therefore a greater area of each of the particles contained in the polishing liquid may be in brought into contact with a certain surface to be polished (i.e., wafer surface). Specifically, when the true sphericity is small, the surface shape is smoother compared to a case in which the true sphericity is big, thus a larger area may be brought into in contact with the wafer surface compared to a case in which the surface shape is very uneven. As a result, it can be considered that the polishing rate for the interlayer insulating film is increased.

(I-iv. Blending Amount)

The blending amount of the colloidal silica in the polishing liquid for CMP is preferably 2.0 to 8.0% by mass relative to 100% by mass of the polishing liquid for CMP. When the blending amount of the colloidal silica having the characteristics as described above is 2.0% by mass or more, there is a tendency that a favorable polishing rate for the interlayer insulating film is obtained. When it is 8.0% by mass or less, it is easier to inhibit agglomeration and precipitation of the particles, and as a result there is a tendency that favorable dispersion stability and storage stability are obtained. Furthermore, the blending amount mentioned herein indicates a blending amount in the prepared state in which it can be used for the CMP polishing process. It does not indicate a blending amount at the time of fractional storage or concentrated storage.

### (II. pH of the Polishing Liquid for CMP)

The polishing liquid for CMP of the invention is characterized in that the interlayer insulating film can be polished at a high speed. However, in order to suitably use the polishing liquid for the over-polishing in the polishing of the barrier metal which will be described below, it is preferable that the polishing rate for the conductive material and the barrier metal is also maintained at a favorable speed. From this point of view, pH of the polishing liquid of the invention is preferably 1.5 to 5.5. When pH is 1.5 or more, corrosion of the conductive material can be easily inhibited, and therefore the dishing, which is caused by excessive polishing of the conductive material, can be also easily inhibited. Furthermore, compared to a strongly acidic case, handling is easier. In addition, when pH is 5.5 or less, a favorable polishing rate can be obtained even for the conductive material and the barrier metal.

### (III. Medium)

Medium for the polishing liquid for CMP is not specifically limited. However, it preferably contains water as a main component. More specifically, de-ionized water, ion-exchanged water and ultra pure water and the like are preferable.

If necessary, the polishing liquid for CMP may contain an organic solvent other than water. The organic solvent can be used as an aid of a solubilizer for a component which is nearly insoluble in water or used for the purpose of improving wettability of the polishing liquid for CMP to a surface to be polished. The related techniques are disclosed in the pamphlets or the like of the international publication WO03/038883 and WO00/39844 and the disclosures thereof are incorporated herein by reference. The organic solvent to be used for the polishing liquid for CMP of the invention is not specifically limited. However, a solvent which is freely miscible with water is preferable, and it can be used in the form of a single kind or in the form of a combination of two or more kinds.

An example of the organic solvent used as an aid of the solubilizer includes a polar solvent such as alcohol and acetic acid. Further, as for the organic solvent for the purpose of improving wettability, glycols, glycol monoethers, glycol diethers, alcohols, carbonic acid esters, lactones, ethers, ketones, phenols, dimethylformamide, n-methylpyrrolidone, ethyl acetate, ethyl lactate, sulfolane and the like can be mentioned. Preferred is at least one selected from glycol monoethers, alcohols and carbonic acid esters.

When the organic solvent is blended, the blending amount of the organic solvent is preferably 0.1 to 95% by mass, and more preferably 0.2 to 50% by mass relative to 100% by mass of the polishing liquid for CMP. Most preferably, it is 0.5 to 10% by mass. When the blending amount is 0.1% by mass or more, effect of improving the wettability of the polishing liquid to a substrate is easily obtained. When it is 95% by mass or less, difficulty in handling the polishing liquid for CMP is reduced, and therefore it is favorable in terms of production process.

Furthermore, a blending amount of water corresponds to the residual amount. If contained, the blending amount of water is not specifically limited. Furthermore, water is also used as diluents to dilute the polishing liquid which has been concentrated and stored to a desired concentration.

### (IV. Other Components)

The primary purpose of the polishing liquid for CMP of the invention is to obtain a polishing rate that is appropriate for the conductive material and the barrier metal. It may contain a metal oxide dissolving agent or a metal oxidant (Hereinbelow, abbreviated as an oxidant). In addition, when pH of the polishing liquid for CMP is low, etching may occur in the conductive material. Thus, for the purpose of inhibiting the etching, an anti-corrosive agent for metal can be contained. Hereinbelow, these components will be explained.

The metal oxide dissolving agent which can be used for the polishing liquid for CMP of the invention is not particularly limited if it has a function of controlling pH and a function of dissolving a conductive material. Specific examples of the agent include organic acids, organic acid esters, salts of the organic acid, inorganic acids and salts of the inorganic acid and the like. The representative example of the salts is ammonium salt. Among these, in terms of effective suppression of the etching speed while a CMP speed is maintained at a practical level, an organic acid such as formic acid, malonic acid, malic acid, tartaric acid, citric acid, salicylic acid, adipic acid, and the like are preferable. Furthermore, in terms of easy obtainment of a high polishing rate for the conductive material, an inorganic acid such as sulfuric acid is preferable. These metal oxide dissolving agents may be used singly or in the form of a combination of two or more kinds thereof. A mixture of the organic acid and the inorganic acid may be also used.

When the metal oxide dissolving agent is blended, the blending amount is preferably 0.001% by mass or more, and more preferably 0.002% by mass or more relative to 100% by mass of the polishing liquid for CMP, in terms of easy obtainment of a favorable polishing rate for the conductive material and the barrier metal. Most preferably, it is 0.005% by mass or more. Furthermore, the blending amount is preferably kept at 20% by mass or less, because, under such condition, suppression of the etching is induced more easily, and as a result, the occurrence of roughness on the polished surface tends to be inhibited. More preferably, it is 10% by mass or less, and most preferably 5% by mass or less.

The metal anti-corrosive agent which can be used for the polishing liquid for CMP of the invention is not particularly limited if it has an ability of forming a protective layer for the conductive material. Specific examples of the agent include compounds having a triazole skeleton, compounds having a pyrazole skeleton, compounds having a pyrimidine skeleton, compounds having an imidazole skeleton, compounds having a guanidine skeleton, compounds having a thiazole skeleton, and compounds having a tetrazole skeleton and the like. These compounds may be used singly, or in the form of a combination of two or more kinds thereof.

The blending amount of the metal anti-corrosive agent is preferably 0.001% by mass or more, and more preferably 0.002% by mass or more relative to 100% by mass of the polishing liquid for CMP, to obtain its activity. Furthermore, in terms of inhibiting reduction in the polishing rate, the blending amount is preferably 10% by mass or less, more preferably 5% by mass or less, and most preferably 2% by mass or less.

An oxidant which can be used for the polishing liquid for CMP of the invention is not particularly limited if it has an ability of oxidizing the conductive material described above. Specific examples of the metal oxidant include hydrogen peroxide, nitric acid, potassium periodate, hypochlorous acid and aqueous ozone and the like, and hydrogen peroxide is particularly preferable among them. These agents may be used singly, or in the form of a combination of two or more kinds thereof.

Since contamination with alkali metals, alkali earth metals or halogenated compounds is undesirable when the substrate is a silicon substrate having integrated circuit elements, oxidants that do not contain any non-volatile components are desirable. Hydrogen peroxide is most suitable since aqueous ozone exhibits huge change of the composition with time. On the other hand, an oxidant containing non-volatile components may be used when the substrate body for application is a glass substrate or the like having no semiconductor elements.

When the oxidant is blended, the blending amount is preferably 0.001% by mass or more, and more preferably 0.005% by mass or more relative to 100% by mass of the polishing liquid for CMP, to obtain its activity of oxidizing metals. Most preferably, it is 0.01% by mass or more. Furthermore, in terms of inhibiting any roughness which may occur on the polished surface, it is preferably 50% by mass or less, more preferably 20% by mass or less, and most preferably 10% by mass or less. Furthermore, when hydrogen peroxide is used as the oxidant, the aqueous hydrogen peroxide solution is blended so as to achieve the final concentration of hydrogen peroxide to be within the range described above because the hydrogen peroxide is available as aqueous hydrogen peroxide solution.

As explained in the above, the polishing liquid for CMP of the invention is characterized in that it has a high polishing rate for the interlayer insulating film and has a broad margin for the materials constituting the polishing liquid. Specifically, according to the conventional technique, when a type or blending amount of one component is modified to improve one characteristic of the polishing liquid for CMP, delicate balance among various components tends to get disrupted and other characteristics are also impaired. For example, if a type of one component is changed to improve flatness of the polished surface, the polishing rate, which is the most important factor, may be reduced.

However, as the polishing liquid for CMP of the invention has a highly improved polishing ability (in particular, polishing rate) by the polishing particles described above, adjustment of characteristics by changing with other components is easy. For example, by changing the type and addition amount or the like of the components as described in the above section “IV. Other components,” various types of polishing liquid can be prepared. This means that, even when the polishing rate of the conductive material or the barrier metal is increased or decreased based on common knowledge in the art, the polishing rate for the interlayer insulating film is not much affected. Therefore, by changing other components, a polishing liquid for CMP having a high selectivity in which the polishing rate for the barrier metal is faster than the polishing rate for the conductive material, or a polishing liquid for CMP having no selectivity in which the polishing rate of the barrier metal is the same as the polishing rate of the conductive material, can be easily produced.

Furthermore, according to the polishing liquid of the invention, even with a relatively small addition amount of polishing particles, a relatively high polishing rate for the interlayer insulating film can be obtained, and therefore it is advantages in terms of cost.

Of course, it is possible to add a great amount of polishing particles as long as the particles are not adversely affected by agglomeration and precipitation, etc. However, since only a small amount is sufficient, the polishing liquid may be concentrated to a high concentration during transport and storage, for example. Specifically, a slurry containing the colloidal silica particles is separately stored from one or two liquids containing the other components other than the colloidal silica. Then, at the time of CMP polishing process, they may be admixed with each other and used in combination. For example, 2.0 to 8.0% by mass of the blending amount of the colloidal silica particles may be combined relative to 100% by mass of the polishing liquid for CMP, and used.

### (Fractional Storage)

As explained in the above, the polishing rate can be adjusted to a desirable value by incorporating the metal oxide dissolving agent and the like. However, as a result, stability of the polishing particles may be impaired. In order to avoid this, in the polishing liquid of the invention, a slurry containing at least the colloidal silica particles can be separately stored from an additive liquid containing other components (e.g., a component which may impair the dispersion stability of the colloidal silica). For example, in the case of the polishing liquid containing the colloidal silica, metal oxide dissolving agent, oxidant, metal anti-corrosive agent, and water, the oxidant which has a potential of affecting the dispersion stability of the colloidal silica may be stored separately from the colloidal silica.

### (Concentrated Storage)

As having the two-axis average primary particle diameter, the association degree, and the true sphericity within the range described above, the colloidal silica used for the polishing liquid for CMP of the invention has the very favorable dispersion property, and therefore can be dispersed at a high concentration in a medium. The conventional colloidal silica can be contained in an amount of at most 10% by mass even when the dispersion property is improved by a known method. When more amount than the above is added, agglomeration and precipitation occur. However, the colloidal silica used for the polishing liquid for CMP of the invention can be dispersed in an amount of 10% by mass or more in the medium and up to 12% by mass can be easily dispersed in the medium. Furthermore, as much as 18% by mass of the colloidal silica can be dispersed. This means that, the polishing liquid for CMP of the invention can be transported and stored in a highly concentrated state, and it is very advantageous in terms of process. It suggests that, when a polishing liquid for CMP containing 5% by mass of the colloidal silica is used, for example, it can be three-times concentrated during the transport and storage.

More specifically, by preparing respectively a concentrated slurry containing 10% by mass or more of the colloidal silica, an additive liquid containing the other components and a diluents, and by mixing them right before the polishing process or by supplying them while controlling the flow rate to obtain a desired concentration at the time of polishing, a polishing liquid for CMP can be obtained. In addition, it is also possible to incorporate components other than colloidal silica in the diluents. For example, a concentrated slurry, an aqueous hydrogen peroxide serving as a diluents containing an oxidant therein, and an additive liquid containing the remaining components can be separately prepared.

### (V. Use and Method for Use)

The polishing liquid of the invention can be applied for forming a wiring layer in a semiconductor device. For example, it can be used for CMP applied to a substrate having a layer of conductive material, a layer of barrier metal and an interlayer insulating film.

The polishing method of the invention is a method of polishing a substrate having: an interlayer insulating film having concave regions and convex regions on the surface thereof; a barrier metal layer covering the surface of the interlayer insulating film; and a conductive material layer covering the barrier metal while filling the concave regions. This polishing method comprises the steps of:

a first polishing step of polishing the conductive material layer and thereby exposing the barrier metal at convex regions; and

a second polishing step of polishing at least the barrier metal and the conductive material layer in the concave regions. In addition, according to the second polishing process, after reaching the end point at which the interlayer insulating film at the convex regions is exposed, a certain portion of the thickness of the interlayer insulating film at the convex regions may be further polished to obtain flatness. In addition, according to the second polishing process, chemical and mechanical polishing is carried out while the polishing liquid for CMP of the invention is supplied.

Examples of the conductive material include any materials containing metal as a main component such as copper, copper alloy, copper oxide, copper alloy oxide, tungsten, tungsten alloy, silver, and gold. Among these materials, preferred are those having copper as a main component. As for the conductive material layer, a film obtained from the materials by film formation according to a known method such as a sputtering method or a plating method can be used.

Examples of the interlayer insulating film include a silicon coating film and an organic polymer film.

Examples of the silicon coating film include a silica-based coating film of silicon dioxide, fluorosilicate glass, organosilicate glass obtained by using trimethylsilane or dimethoxysilane as a starting material, silicon oxynitride, or hydrogenated silsesquioxane, silicon carbide and silicon nitride.

Furthermore, an example of the organic polymer film includes a wholly aromatic-low dielectric constant interlayer insulating film. An organosilicate glass is particularly preferable. These films may be formed by the CVD method, spin-coat method, dip-coat method or spray method. A specific example for the insulating film includes an interlayer insulating film used in the LSI manufacturing process, and in particular in a process of forming multi-level wirings.

The barrier metal layer is formed to prevent the conductive material from diffusing into the interlayer insulating film and to improve the adhesion between the insulating film and the conductive material. At least one barrier metal selected from tantalum, tantalum nitride, tantalum alloy, and other tantalum compounds; titanium, titanium nitride, titanium alloy and other titanium compounds; tungsten, tungsten nitride, tungsten alloy and other tungsten compounds; ruthenium, and other ruthenium compounds, and a laminated film containing this barrier metal can be mentioned.

When the polishing is carried out by using a polishing pad, for example, the machine for the polishing may be an ordinary polishing machine having: a holder for holding a substrate to be polished; and a table to which a polishing pad is attached and to which a motor giving a variable rotation speed is connected.

The polishing pad may be a common non-woven fabric, a foamed polyurethane, a porous fluorine resin or the like, and is not particularly limited.

Conditions for the polishing are not particularly limited, and the rotational speed of the table is preferably as low as 200 min⁻¹ or less so as for the substrate not to fly off. The polishing pressure of a semiconductor substrate having a surface to be polished onto the polishing pad is preferably within the range of 1 to 100 kPa. The pressure is more preferably within the range of 5 to 50 kPa in order to satisfy homogenous CMP speed in a wafer surface and flatness of pattern.

During the polishing, the polishing liquid for CMP of the invention is continuously supplied to the polishing pad by a pump or the like. The supply amount thereof is not particularly limited, but is preferably an amount permitting the polishing pad surface to be covered constantly with the polishing liquid. After the polishing, it is preferred to wash the substrate sufficiently with flowing water, to remove water droplets adhering onto the substrate by using a spin drier or the like, and then to dry the substrate. It is preferable that, after the chemical and mechanical polishing process according to the invention is carried out, a process of washing the substrate is further carried out.

The polishing method of the invention can be applied, for example, to formation of a wiring layer in a semiconductor device.

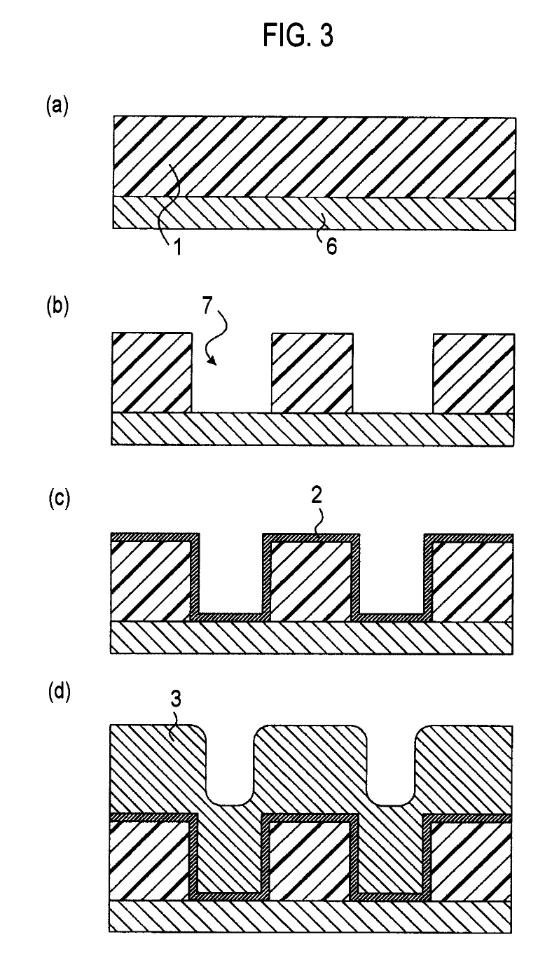

Hereinbelow, the embodiment for carrying out the polishing method of the invention will be explained in view of the process of forming a wiring layer in a semiconductor device as shown in FIG. 3.

First, as shown in FIG. 3(a), an interlayer insulating film 1 of silicon dioxide or the like is laminated on a silicone substrate 6. Subsequently, as shown in FIG. 3(b), according to a known means such as formation of a resist layer and etching, concave regions 7 (exposed regions of the substrate) in a certain pattern are formed on the surface of the interlayer insulating film to form the interlayer insulating film having both the convex and concave regions. Next, as shown in FIG. 3(c), on the interlayer insulating film, a barrier metal 2 such as tantalum or the like covering the interlayer insulating film is formed into a film along the uneven surface by a vapor deposition method, CVD method or the like.

In addition, as shown in FIG. 3(d), a conductive material 3 layer is formed by vapor-deposition, by plating method, by CVD method, or the like, the conductive material layer consisting of a metal for wiring such as copper and covering the barrier metal so as to fill the concave regions. The interlayer insulating film 1, the barrier metal 2 and the conductive material 3 are preferably formed in thicknesses within the range of 0.01 to 2.0 μm, 1 to 100 nm, and 0.01 to 2.5 μm, respectively.

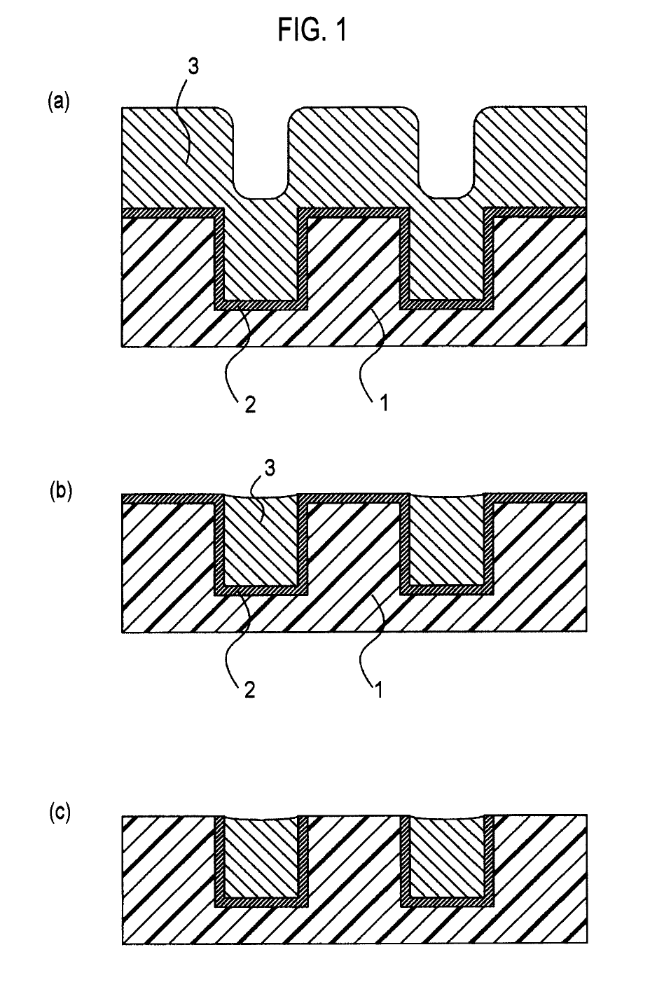

Next, as shown in FIG. 1, the conductive material 3 layer on the surface of the semiconductor substrate is CMP-polished by using the polishing liquid for conductive materials that has a sufficiently high polishing rate ratio of the conductive material to the barrier metal (i.e., first polishing process), for example. As a result, as shown in FIG. 1(b), a desired conductor pattern, in which the barrier metal at the convex regions on the substrate is exposed from the surface and the conductive material film is left in the concave regions, is obtained. The obtained patterned surface can be polished as a surface to be polished in a second polishing process of the polishing method of the invention, in which the polishing liquid for CMP of the invention is used.

During this second polishing process, by using the polishing liquid of the invention which can polish the conductive material, the barrier metal, and the interlayer insulating film, at least the exposed barrier metal and the conductive material in the concave regions are polished by chemical and mechanical polishing.

As shown in FIG. 1(c), at the time point at which the entire interlayer insulating film under the barrier metal at the convex regions is exposed, the conductive material layer which becomes a wiring layer is left in the concave regions, and a desired pattern, in which the end face of the barrier metal is exposed at the boundaries between the convex regions and the concave regions, is obtained; the polishing is terminated.

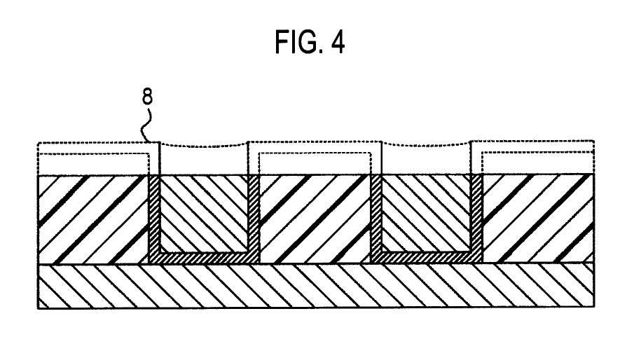

To ensure better flatness at the time of termination of the polishing, as shown in FIG. 4, the over-polishing (for example, when a time required to obtain the desired pattern by the second polishing process is 100 seconds, the polishing is further carried out for 50 seconds in addition to 100 seconds, it is called 50% over-polishing) may be carried out such that the polishing proceeds up to some extent in depth, in which part of the interlayer insulating film at the convex regions is included. In FIG. 4, an over-polished region 8 is indicated by broken line.

On the metal wiring obtained as described above, another interlayer insulating film and a second-layer of metal wirings are further formed, a further interlayer insulating film is again formed between and on the wirings, and then polishing is carried out to obtain a flat and smooth surface over the entire area of the semiconductor substrate. By repeating this process for a certain number of times, a semiconductor device having the desired number of wiring layers can be manufactured (not illustrated).

The polishing liquid for CMP of the invention can be used not only to polish a silicone compound film formed on the semiconductor substrate described above but also to polish an inorganic insulating film such as a silicon dioxide film, glass, or silicon nitride that is formed on a circuit board having a predetermined circuit thereon; an optical glass such as a photomask, a lens, or a prism; an inorganic conductive film made of ITO; an optical integrated circuit, an optical switching element, or an optical waveguide, each of which is composed of glass and a crystalline material; an optical fiber end face; an optical monocrystal such as scintillator; a solid laser monocrystal; a sapphire substrate for a blue laser LED; a semiconductor monocrystal such as SiC, GaP, or GaAs; a glass substrate for a magnetic disc; and a substrate for a magnetic head.

### EXAMPLES

Hereinbelow, the invention is explained in view of the examples. However, the invention is not limited to the examples.

### Example 1 to 3, Comparative Example 1 to 8

### (I-1) Preparation of the Polishing Liquid for CMP

5.0% by mass of colloidal silica A to K as polishing particles (polishing grain), 0.5% by mass of malic acid as a metal oxide dissolve agent, 0.1% by mass of benzotriazole as a metal anti-corrosive agent, 0.5% by mass of hydrogen peroxide as an oxidant, and 93.9% by mass of water were admixed with one another to prepared a polishing liquid for CMP. In addition, 30% aqueous solution of hydrogen peroxide was used to obtain the blending ratio of hydrogen peroxide described above. Each value of the two-axis average primary particle diameter (R₁), true sphericity S₁/S₀, and association degree (Rₛ/R₁) of the colloidal silica A to K is summarized in Table 1.

### (I-2) Preparation of the Polishing Liquid for CMP to Evaluate Dispersion Stability

In order to evaluate dispersion stability of the polishing particles in the polishing liquids, a polishing liquid for CMP was prepared in the same manner as in the above section (I-1) except that the blending amount of the polishing particles is changed from 5.0% by mass to 12% by mass and the blending amount of water is changed from 93.9% by mass to 86.9% by mass.

### (I-3) Method of Measuring Characteristics of the Polishing Particles

Furthermore, the characteristics of the colloidal silica A to K shown in Table 1 were identified as follows.

### (1) Two-Axis Average Primary Particle Diameter (R₁)

First, an appropriate amount of each of colloidal silica A to K usually dispersed in water was put into a container. Next, a wafer having patterned wirings thereon is cut into cubes to produce chips each having a size of 2 square-cm and the resulting chip was immersed in the container for approximately 30 seconds. After that, the chip was taken out and washed with pure water for approximately 30 seconds. The chip was then dried by nitrogen blowing. The chip was placed on a sample stage for SEM observation. With application of acceleration voltage of 10 kV, the particles were observed with a magnification ratio of 100,000 and the image was taken.

Twenty particles were arbitrarily selected from the obtained image. A rectangular shape was drawn (i.e., circumscribed rectangle) to have the longest major axis while circumscription was made around the selected particle. When the length of the major axis and the length of the minor axis of the circumscribed rectangle 5 is L and B, respectively, the two-axis average primary particle diameter was calculated as (L+B)/2 for a single particle. The same process was repeated for the twenty arbitrarily selected particles, and the average value obtained therefrom was defined as the two-axis average primary particle diameter (R₁) of the invention.

### (2) True Sphericity (S₁/S₀)

By using colloidal silica A to K, specific surface areas (S₁) of the colloidal silica particles were measured according to BET method. Specifically, about 100 g of each of colloidal silica A to K dispersed in water was put into a dryer and dried at 150° C. to obtain silica particles. The resulting silica particles (about 0.4 g) was put into a measurement cell of an apparatus for measuring the BET specific surface area (trade name: NOVA-1200, manufactured by YUASA-IONICS Co., Ltd.) and then deaerated at 150° C. for 60 minutes under vacuum. The area was obtained according to a constant volume method wherein nitrogen gas is used as an adsorption gas, and the obtained value was taken as a BET specific surface area. The measurement was carried out twice and the average value was taken as the BET specific surface area (S₁) of the invention.

Furthermore, by assuming a true sphere which has the same particle diameter as the two-axis average primary particle diameter (R₁) as obtained from the above (1), the specific surface area of the true sphere, i.e., S₀, was obtained. From the value obtained, S₁/S₀ was calculated.

### (3) Association Degree (Rₛ/R₁)

Using the polishing liquids of the Example 1 to 3 and the Comparative example 1 to 8, the average value of the secondary particle diameter of colloidal silica A to K in the polishing liquid was measured by using the dynamic light scattering particle size distribution analyzer (Model Number N5, manufactured by Beckman Coulter, Inc.) in the following way, and the resulting value was taken as Rₛ. Specifically, an appropriate amount of the polishing liquid for CMP was taken and diluted with water, if necessary, to be within the range of scattering light intensity that is required by a dynamic light scattering particle size distribution analyzer, yielding a sample for measurement. Then, this measurement sample was applied to a dynamic light scattering particle size distribution analyzer, and the obtained D50 value was taken as the average value of the secondary particle diameter (Rₛ).

By calculating the ratio of this Rₛ to the two-axis average primary particle diameter (R₁) which had been obtained from (1) above, the association degree (Rₛ/R₁) was obtained.

### (II: Items for Evaluation)

### (II-1: Polishing Rate)

Using the polishing liquid obtained from the section (I-1) above, three kinds of blanket substrates (i.e., blanket substrate a to c) were polished and washed under the condition described below.

### (Polishing Condition)

Apparatus for polishing and washing: Polishing machine for CMP (product name: MIRRA, manufactured by Applied Materials, Inc.)

Polishing pad: foamed polyurethane resin

Table rotation speed: 93 rotations/min

Head rotation speed: 87 rotations/min

Pressure for polishing: 14 kPa

Supply amount of polishing liquid: 200 ml/min

Time for polishing: 60 seconds

### (Blanket Substrate)

Blanket Substrate (a):

A silicone substrate having silicon dioxide with a thickness of 1000 nm that is formed by CVD method

Blanket Substrate (b):

A silicone substrate having a tantalum nitride film with a thickness of 200 nm that is formed by sputtering method

Blanket Substrate (c):

A silicone substrate having a copper film with a thickness of 1600 nm that is formed by sputtering method

For the three blanket substrates obtained after the polishing and washing, polishing rates were obtained as follows.

For the blanket substrate (a), film thickness before and after the polishing was measured by using the apparatus for measuring a film thickness, RE-3000 (manufactured by Dainippon Screen Mfg. Co. Ltd.), and the polishing rate was determined from the difference between two film thicknesses measured.

For each of the blanket substrate (b) and the blanket substrate (c), film thickness before and after the polishing was measured by using the apparatus for measuring metal film thickness, VR-120/08S (manufactured by Hitachi Kokusai Electric, Inc.), and the polishing rate was determined from the difference between two film thicknesses measured.

Measurement results of the polishing rate are described in Table 1.

### (II-2: Evaluation of Dispersion Stability)

Each of the polishing liquids for CMP, which has been prepared for the evaluation of dispersion stability in the section (I-2) above, was stored respectively in an incubator at 60° C. for two weeks. After that, precipitation of the polishing particles in the polishing liquid was visually examined to evaluate the dispersion stability of the polishing particles in the polishing liquid. The results are summarized in Table 1.

### (III) Evaluation Results

Regarding the polishing liquid for CMP in which the colloidal silica of the Example 1 to 3 is used, it was confirmed that the dispersion stability is favorable and the polishing of the interlayer insulating film can be carried out at a high speed of from 90 to 97 nm/min.

On the other hand, the colloidal silica particles of the Comparative example 1 to 8 are not the particles which satisfy the requirements (1) to (3) described above. The dispersion stability was either favorable or unfavorable for these particles. In addition, the polishing rate for the interlayer insulating film was only about 40 to 70 nm/min.

TABLE 1

| | | Example | | | Comparative Example | | | | | | | |
|---|---|---|---|---|---|---|---|---|---|---|---|---|
| | | 1 | 2 | 3 | 1 | 2 | 3 | 4 | 5 | 6 | 7 | 8 |
| Polishing | Type of Polishing | A | B | C | D | E | F | G | H | I | J | K |
| particles | particles | | | | | | | | | | | |
| | Two-axis average | 46.5 | 41.5 | 49.5 | 46.4 | 21.5 | 47.1 | 101.5 | 45.4 | 43.8 | 27.5 | 61.3 |
| | primary particle | | | | | | | | | | | |
| | diameter R₁ [nm] | | | | | | | | | | | |
| | Secondary particle | 51.3 | 45.2 | 55.4 | 62.4 | 26.8 | 52.5 | 198 | 56.3 | 82.4 | 29.6 | 63.6 |
| | diameter Rs[nm] | | | | | | | | | | | |
| | Association degree | 1.10 | 1.09 | 1.12 | 1.34 | 1.25 | 1.11 | 1.95 | 1.24 | 1.88 | 1.08 | 1.04 |
| | BETspecific surface | 68.9 | 78.2 | 64.7 | 78.0 | 162 | 87.9 | 37.0 | 79.1 | 91.0 | 122 | 69.5 |
| | area S₁[m²/g] | | | | | | | | | | | |
| | Specific surface area | 62.9 | 70.5 | 59.1 | 63.1 | 136 | 62.1 | 28.8 | 64.5 | 66.8 | 106.4 | 47.7 |
| | S₀[m2/g] of true sphere | | | | | | | | | | | |
| | having particle | | | | | | | | | | | |
| | diameter R₁ | | | | | | | | | | | |
| | S₁/S₀ | 1.10 | 1.11 | 1.09 | 1.24 | 1.19 | 1.42 | 1.28 | 1.23 | 1.36 | 1.15 | 1.46 |
| Polishing | Silicon dioxide blanket | 92 | 90 | 97 | 68 | 41 | 57 | 65 | 68 | 60 | 44 | 67 |
| rate[nm/min] | substrate (a) | | | | | | | | | | | |
| | Tantalum nitride blanket | 75 | 72 | 74 | 78 | 73 | 71 | 62 | 73 | 67 | 70 | 73 |
| | substrate (b) | | | | | | | | | | | |
| | Copper blanket | 36 | 38 | 36 | 35 | 39 | 38 | 33 | 36 | 35 | 35 | 33 |
| | substrate (c) | | | | | | | | | | | |

| | | | | | | | | | | | |
|---|---|---|---|---|---|---|---|---|---|---|---|
| Precipitation of polishing particles | No | No | No | Yes | Yes | Yes | Yes | Yes | Yes | No | No |

### (Determination of the Amount of the Polishing Particles Contained in the Polishing Liquid for CMP of Example 1)

The polishing liquid for CMP (Example 4) was prepared in the same manner as the above section (I-1) except that the blending amount of the polishing particles in the polishing liquid for CMP, in which the colloidal silica of Example 1 is used, is changed from 5.0% by mass to 3.0% by mass and the blending amount of water is changed from 93.9% by mass to 96.9% by mass. Furthermore, the polishing liquid for CMP (Example 5) was prepared in the same manner as the section (I-1) above except that the blending amount of the polishing particles is changed from 5.0% by mass to 7.0% by mass and the blending amount of water is changed from 93.9% by mass to 90.9% by mass.

Polishing rates of the above described two liquids for the silicon dioxide substrate (a), the tantalum nitride blanket substrate (b) and the copper blanket substrate (c) were evaluated according to the same method as described the above. Results are shown in Table 2, along with the results of the Example 1.

As shown in the table, it was confirmed that, even when the blending amount of the polishing particles in the polishing liquid for CMP is changed to some extent, the polishing rate for the interlayer insulating film is maintained at 81 to 102 nm/min or so, which is a relatively high polishing rate compared to the Comparative example 1 to 8.

TABLE 2

| | | Example 1 | Example 4 | Example 5 |
|---|---|---|---|---|
| | Type of polishing particles | A | A | A |
| Polishing rate | Silicon dioxide blanket substrate (a) | 92 | 81 | 102 |
| [nm/min] | Tantalum nitride blanket substrate (b) | 75 | 74 | 78 |
| | Copper blanket substrate (c) | 36 | 36 | 37 |

### INDUSTRIAL APPLICABILITY

According to the invention, a polishing liquid for CMP which is useful for polishing an interlayer insulating film at a high polishing rate can be obtained. As a result, throughput can be improved by shortening the time required for the polishing process.

Further, even for a case in which the addition amount of the polishing particles is relatively small compared to the conventional technique, a high polishing rate for the interlayer insulating film can be obtained.

Further, as only a small addition amount of the polishing particles is used and the polishing liquid can be concentrated to a higher concentration compared to conventional solution, it has better convenience in terms of storage and transport. In addition, an application method which is customized to the needs of customer and has high level of freedom can be provided.

Still further, the polishing method of the invention, which is employed for chemical and mechanical polishing by using the polishing liquid for CMP, has high productivity and is suitable for manufacturing a highly reliable semiconductor device and other electronic instruments which are excellent in miniaturization, thinning of film thickness, dimensional accuracy and electrical characteristics.

### EXPLANATION OF REFERENCE NUMERALS

1 Interlayer insulating film
2 Barrier layer
3 Conductive material
4 Particle
5 Circumscribed rectangle
6 Substrate
7 Concave region
8 Over-polished region
L Length of the major axis of the circumscribed rectangle
B Length of the minor axis of the circumscribed rectangle

1. A polishing liquid for CMP comprising:
a medium; and
colloidal silica particles dispersed in the medium,
wherein the colloidal silica particles satisfy the following conditions (1) to (3):
(1) a two-axis average primary particle diameter (R₁) obtained from images of twenty arbitrarily selected colloidal silica particles observed by a scanning electron microscope is within the range of 35 to 55 nm;
(2) a value S₁/S₀ obtained by dividing a specific surface area (S₁) of a colloidal silica particle measured by BET method by a calculated specific surface area (S₀) of a true sphere having the same particle diameter as the two-axis average primary particle diameter (R₁) determined by (1) above is 1.20 or less; and
(3) a ratio, association degree: R_{S}/R₁, of a secondary particle diameter (R_{S}) of the colloidal silica particles measured with a dynamic light scattering particle size distribution analyzer and the two-axis average primary particle diameter (R₁) determined by (1) above in the polishing liquid for CMP is 1.30 or less.

2. The polishing liquid for CMP according to claim 1, wherein a blending amount of the colloidal silica particles is 2.0 to 8.0% by mass relative to 100% by mass of the polishing liquid for CMP.

3. The polishing liquid for CMP according to claim 1, further comprising a metal oxide dissolving agent and water.

4. The polishing liquid for CMP according to claim 1, wherein pH is between 1.5 and 5.5.

5. The polishing liquid for CMP according to claim 1, further comprising a metal oxidant.

6. The polishing liquid for CMP according to claim 1, further comprising a metal anti-corrosive agent.

7. The polishing liquid for CMP according to claim 1, wherein a slurry comprising the colloidal silica particles and one or two liquids comprising components other than the colloidal silica are separately stored, wherein the blending amount of the colloidal silica particles is 2.0 to 8.0% by mass relative to 100% by mass of the polishing liquid for CMP when they are combined to be in a usable state in a CMP polishing process.

8. A polishing method of polishing a substrate having: an interlayer insulating film having concave regions; and convex regions on a surface; a barrier metal layer covering the surface of the interlayer insulating film; and a conductive material layer covering the barrier metal and filling the concave regions, comprising the steps of:
a first polishing step of polishing the conductive material layer and thereby exposing the barrier metal at convex regions; and
a second polishing step of polishing at least the barrier metal and the conductive material layer in the concave regions,
wherein during the second polishing process, chemical and mechanical polishing is carried out while the polishing liquid for CMP described in claim 1 is supplied, thereby exposing the interlayer insulating film at the convex regions.

9. The polishing method according to claim 8, wherein the interlayer insulating film is a silicon coating film or an organic polymer film.

10. The polishing method according to claim 8, wherein the conductive material comprises copper as a main component.

11. The polishing method according to claim 8, wherein the barrier metal a barrier metal that prevents the conductive material from diffusing into the interlayer insulating film and comprises at least one selected from the group consisting of tantalum, tantalum nitride, tantalum alloy, other tantalum compounds, titanium, titanium nitride, titanium alloy, other titanium compounds, tungsten, tungsten nitride, tungsten alloy, other tungsten compounds, ruthenium, and other ruthenium compounds.

12. The polishing method according to claim 1, wherein during the second polishing process, the polishing is further carried out to a portion of a thickness of the interlayer insulating film at convex regions.
